(19) United States
(12) Patent Application Publication
(10) Pub. No.: US 2011/0157817 A1
(43) Pub. Date: Jun. 30, 2011

(54) MOUNTING APPARATUS AND COMPUTER SYSTEM FOR HEAT DISSIPATING MEMBER

(75) Inventor: ZHAN-YANG LI, Shenzhen City (CN)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/841,421

(22) Filed: Jul. 22, 2010

(30) Foreign Application Priority Data
Dec. 31, 2009 (CN) 200920319367.4

(51) Int. Cl. G06F 1/20; F16M 13/02; H05K 5/02

(52) U.S. Cl. 361/679.48; 248/229.2; 248/229.22; 312/223.2; 361/695

(57) ABSTRACT

A mounting apparatus includes a bracket and a locking member. The bracket includes two securing plates, and each securing plate defines a positioning hole. The locking member is configured for being secured to a heat dissipating member and includes a board body and two locking portions located on the board body. The two locking portions engage in the positioning holes from outside of the bracket, and each securing plate is positioned between the board body and each locking portion.

### BACKGROUND

1. Technical Field

The present disclosure relates to a mounting apparatus and a computer system for securing a heat dissipating member.

2. Description of Related Art

In a computer system, a plurality of fans is used for heat dissipation. So, a mounting apparatus is needed to conveniently mount the fans in the computer system.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of a mounting apparatus and a heat dissipating member in accordance with an embodiment.

FIG. 2 is an isometric view of a first locking member of the mounting apparatus of FIG. 1.

FIG. 3 is an assembled view of the heat dissipating member, the first locking member, and a second locking member of FIG. 1.

FIG. 4 is an assembled view of the mounting apparatus and the heat dissipating member of FIG. 1.

FIG. 5 is similar to FIG. 4, but showing a plurality of heat dissipating members assembled.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

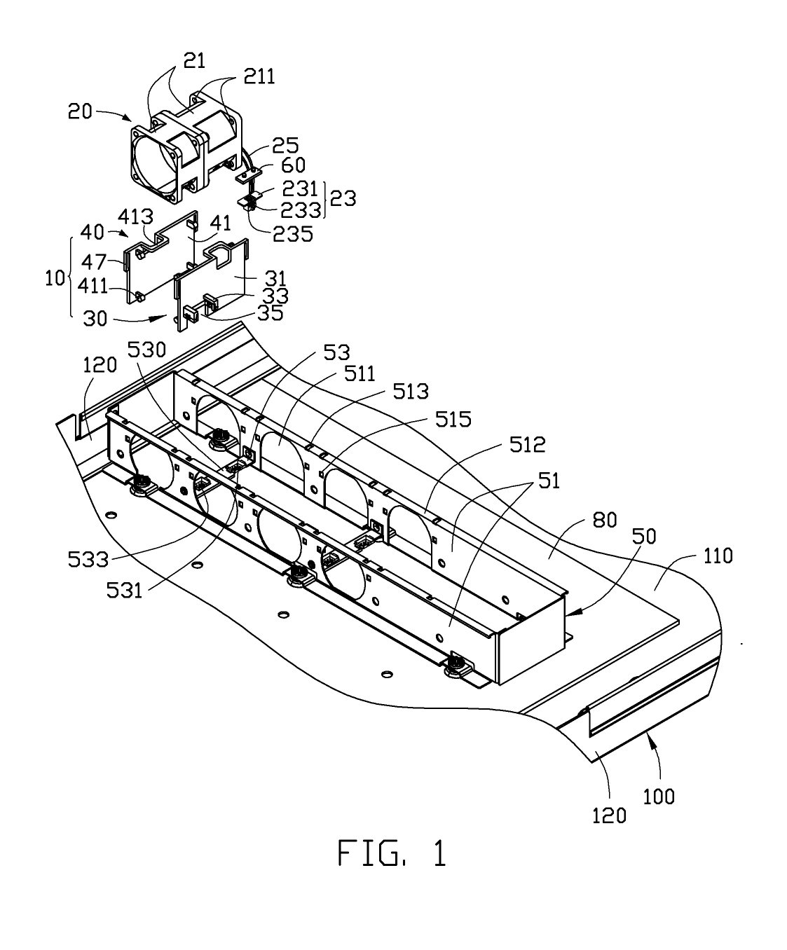

Referring to FIG. 1, a mounting apparatus is configured for securing a heat dissipating member 20. The heat dissipating member 20 includes two fans 21, each fan 21 defining a plurality of mounting holes 211. A male connector 23 is electrically connected to the fans 21 by cables 25. The male connector 23 includes a base board 231 and an inserting portion 233 connected to the base board 231. A receiving hole 235 is defined in the base board 231 to receive an indication board 60. The indication board 60 can display whether the fans 21 are working or not.

The mounting apparatus in accordance with an embodiment includes a chassis 100, a bracket 50, and a locking mechanism 10.

The chassis 100 includes a base plate 110 and two opposite side plates 120 located on the base plate 110. In one embodiment, the side plates 120 are substantially parallel to each other and substantially perpendicular to the base plate 110.

The bracket 50 is secured in the chassis 100 and includes two securing plates 51. In one embodiment, the securing plates 51 are substantially parallel to each other and substantially perpendicular to the base plate 110 and the side plates 120 of the chassis 100. A plurality of ventilation holes 511 is defined in each of the securing plates 51. The ventilation holes 511 of one securing plate 51 correspond to the ventilation holes 511 of another securing plate 51. A flange 512 is located on a top edge of each securing plate 51. In an embodiment, the flanges 512 are perpendicular to the securing plates 51. Each flange 512 defines two through holes 513 at two sides of each ventilation hole 511. A plurality of position holes 515 is defined in each securing plate 51, corresponding to the through holes 513 of each flange 512. Two mounting pieces 530 are secured to the securing plates 51. Each mounting piece 530 is located between two adjacent ventilation holes 511 of each securing plate 51. A first female connector 531 and a second female connector 533 are located on each mounting piece 530.

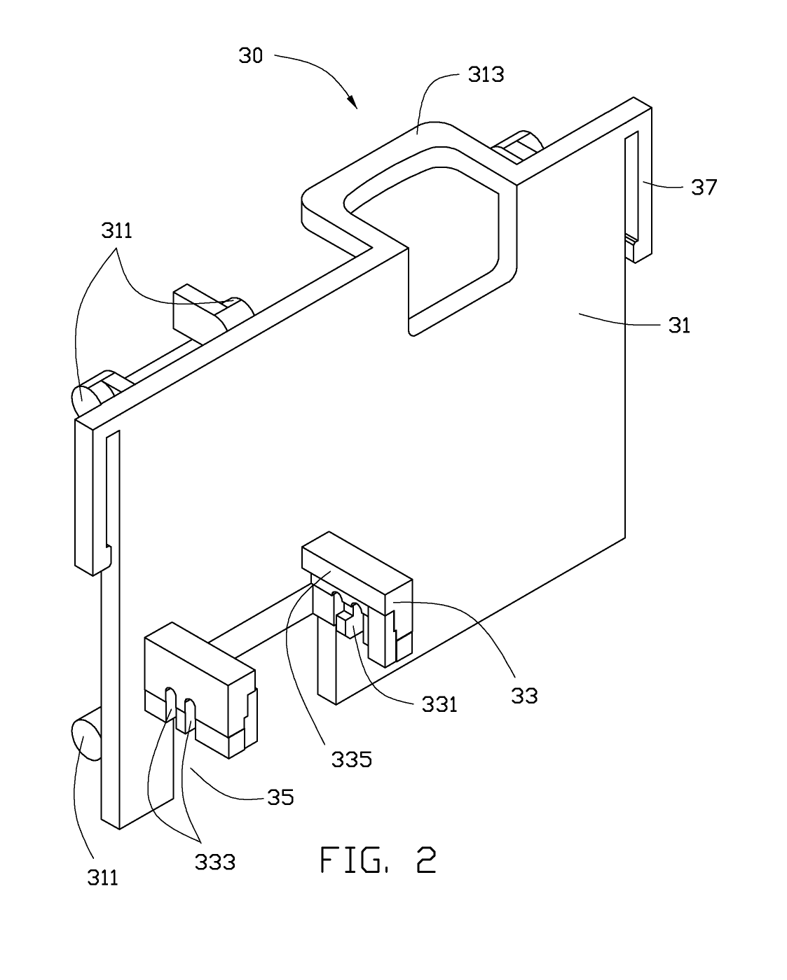

Referring to FIGS. 1-2, the locking mechanism 10 includes a first locking member 30 and a second locking member 40.

The first locking member 30 includes a first board body 31. A plurality of first locking posts 311 is located on a first surface of the first locking member 30 and configured to engage in the mounting holes 211 of the fans 21. Two first locking blocks 33 are located on a second surface of the first board body 31, which is opposite to the first surface. A resilient hook portion 331 is located on each first locking block 33. Two first slots 333 are defined in each first locking block 33 on both sides of the hook portion 331. A first blocking portion 335 protrudes from each first locking block 33. A first operating portion 313 is located on a top edge of the first board body 31. A first cutout 35 is defined in a bottom edge of the first board body 31 under the first locking blocks 33. Two resiliently deformable first locking portions 37 are located on opposite side edges of the first board body 31, configured for engaging in the through holes 513 of the bracket 50.

The second locking member 40 includes a second board body 41. A plurality of second locking posts 411 is located on a first surface of the second locking member 40 and configured to engage in the mounting holes 211 of the fans 21. A second operating portion 413 is located on a top edge of the second board body 41. Two resiliently deformable first locking portions 47 are located on opposite side edges of the first board body 41, configured for engaging in the through holes 513 of the bracket 50. Referring to FIG. 1, the second operating portion 413 extends towards the first operating portion 313, and the first surface of the second locking member 40 is adjacent the first surface of the first locking member 30. In an embodiment, the second locking member 40 may be the same as the first locking member 30.

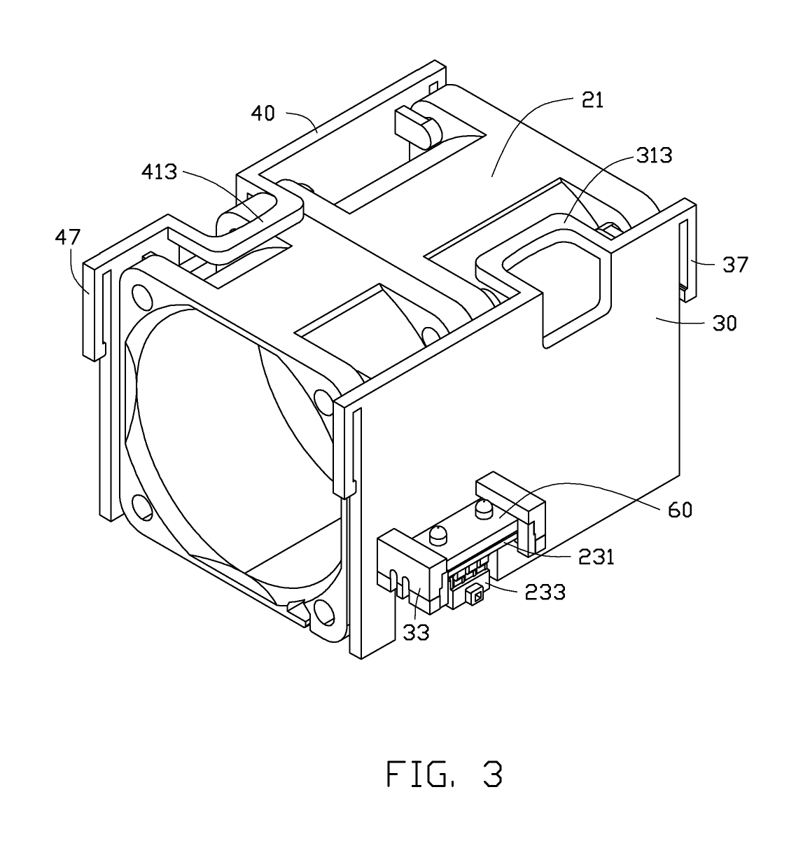

Referring to FIGS. 1-3, the first and second locking members 30 and 40 are secured to the heat dissipating member 20 with the first and second locking posts 311 and 411 engaged in the corresponding mounting holes 211. The indication board 60 is engaged in the receiving hole 235 of the male connector 23. Both the male connector 23 and the indication board 60 are inserted between the first locking blocks 33, the hook portions 331 and the first blocking portions 335.

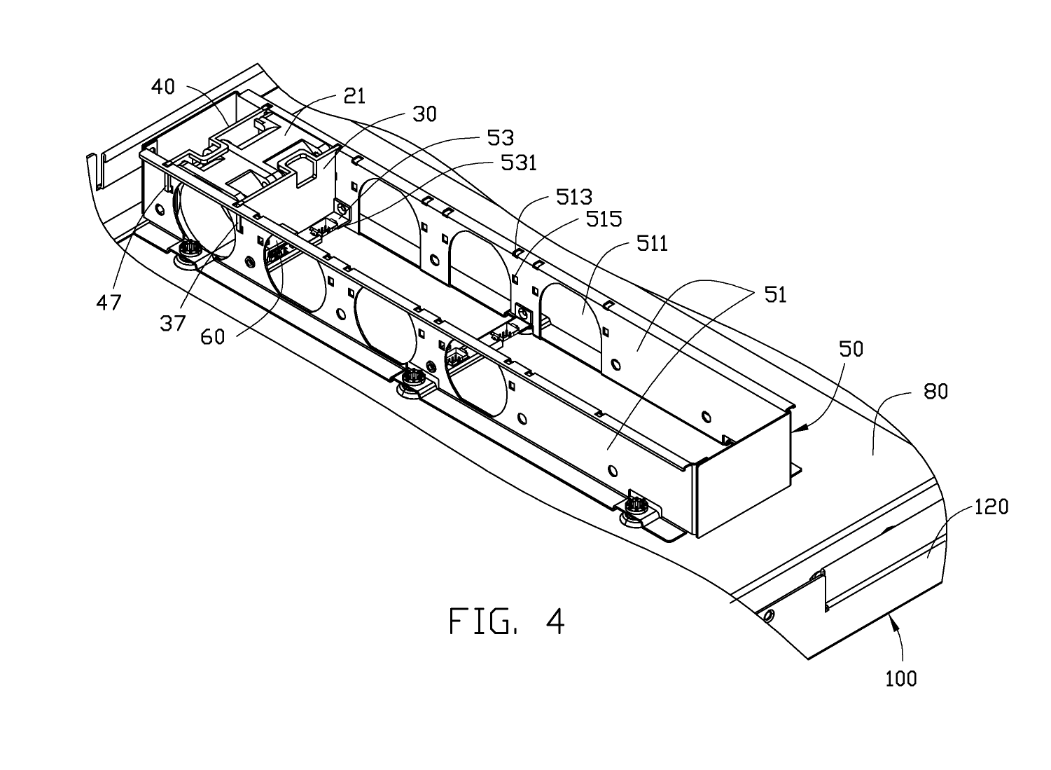

Referring also to FIG. 4, the heat dissipating member 20 and the first and second locking member 30 and 40 are inserted together in between the securing plates 51 of the bracket 50. The heat dissipating member 20 corresponds to one ventilation hole 511 of each securing plate 51. The first and second locking potions 37 and 47 of the first and second locking members 30 and 40 are inserted in the through holes 513 of the flanges 512, positioned outside of the bracket 50, and engaged in the corresponding positioning holes 513. The securing plates 51 are positioned between the board bodies 31 and 41 and the locking portions 37 and 47. The male connector 23 is electronically engaged with the second female connector 533.

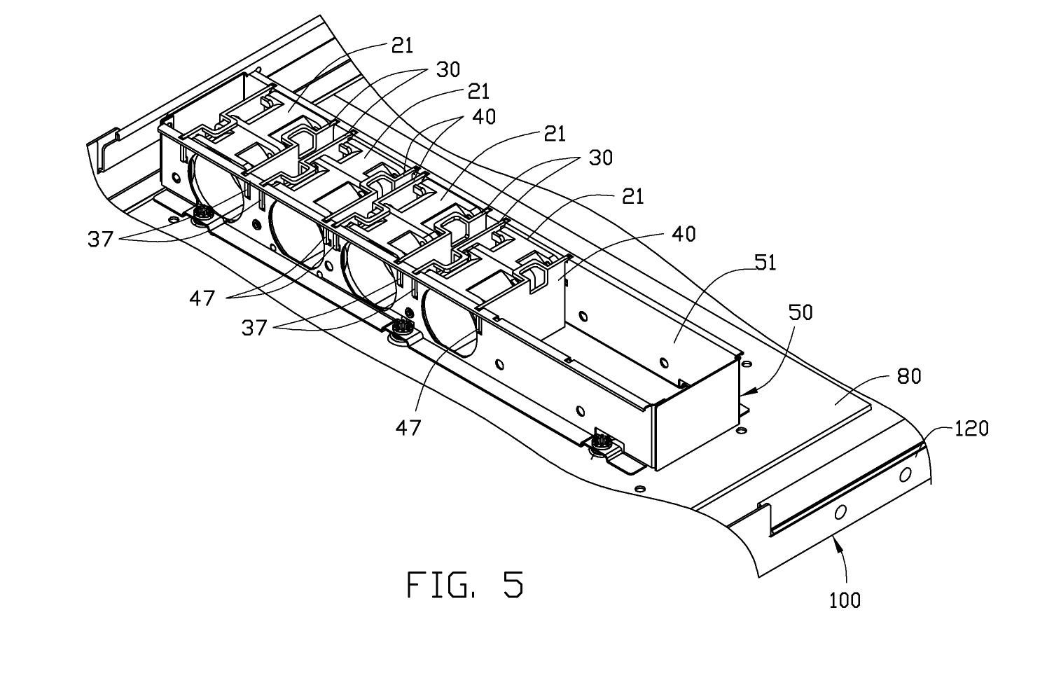

Referring also to FIG. 5, a plurality of heat dissipating members 20 is shown to be secured in the bracket 50.

In one embodiment, the bracket 50 is secured to a circuit board 80. The first and second circuit connectors 531 and 533 are electronically coupled to the circuit board 80. The circuit board 80 is secured to the base plate 110 between the side plates 120.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

1. A mounting apparatus comprising:
a bracket comprising two securing plates, each securing plate defining a positioning hole, a flange located on each securing plate, a through hole defined in each flange, and the through hole corresponding to and separated from the positioning hole; and
a locking member configured for being secured to a heat dissipating member, the locking member comprising a board body and two locking portions connected to two opposite ends of a top edge of the board body, the two locking portions are substantially perpendicular to the top edge and located in a same plane as the board body;
wherein the two locking portions extend through the through hole, a free end of each locking portion engages in the positioning holes from outside of the bracket, and each securing plate is positioned between the board body and each locking portion.

2. (canceled)

3. The mounting apparatus of claim 1, wherein the two securing plates are parallel to each other, and each flange is perpendicular to the securing plates.

4. The mounting apparatus of claim 1, wherein two locking blocks are located on the board body; and a hook portion and a blocking portion are located on each locking block for securing a male connector of the heat dissipating member therebetween.

5. The mounting apparatus of claim 4, wherein the hook portions are resiliently deformable.

6. The mounting apparatus of claim 4, wherein a mounting piece is secured between the securing plates for securing a female connector that is capable of being electronically coupled to the male connector.

7. The mounting apparatus of claim 6, further comprising a chassis, the chassis comprising a base plate; a circuit board secured to the base plate for electronically coupling to the female connector; and the bracket being secured to the circuit board.

8. A computer system comprising:
a heat dissipating member for cooling electronic elements, the heat dissipating member comprising a male connector;
a bracket comprising a securing plate, the securing plate defining a positioning hole, a flange located on each securing plate, a through hole defined in each flange, the through hole corresponding to and separated from the positioning hole, and a female connector secured to the securing plate; and
a locking member secured to the heat dissipating member, the locking member comprising a board body and a locking portion connected to an end of a top edge of the board body, the locking portions are substantially perpendicular to the top edge and located in a same plane as the board body;
wherein the male connector is secured to the board body, the locking portion is extends through the through hole, and a free end of each locking portion engages in the positioning hole to electronically couple the male connector to the female connector.

9. The computer system of claim 8, wherein the securing plate is positioned between the board body and the locking portion.

10. (canceled)

11. The computer system of claim 8, wherein the flange is perpendicular to the securing plate.

12. The computer system of claim 8, wherein two locking blocks are located on the board body; and a hook portion and a blocking portion are located on each locking blocks for securing the male connector therebetween.

13. The computer system of claim 12, wherein the hook portion is resiliently deformable.

14. The computer system of claim 8, wherein a mounting piece is secured to the securing plate, and the female connector is located on the mounting piece.

15. The computer system of claim 8, further comprising a chassis, the chassis comprising a base plate, a circuit board being secured to the base plate and electronically coupled to the female connector, and the bracket being secured to the circuit board.

16. The computer system of claim 8, wherein the heat dissipating member comprises two fans secured to each other; each fan defines a plurality of mounting holes; and a plurality of locking posts is located on the board body and engages in the plurality of mounting holes.
